(19) United States
(12) Patent Application Publication
(10) Pub. No.: US 2010/0072531 A1
(43) Pub. Date: Mar. 25, 2010

(54) Method for Forming a Memory Cell Comprising a Capacitor Having a Strontium Titaniumoxide Based Dielectric Layer and Devices Obtained Thereof

(75) Inventors: Jorge Kittl, Waterloo (BE); Mihaela Ioana Popovici, Leuven (BE); Nicolas Menou, Westerlo (BE); Dirk Wouters, Leuven (BE)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: IMEC, Leuven (BE)

(21) Appl. No.: 12/564,577

(22) Filed: Sep. 22, 2009

Related U.S. Application Data
(60) Provisional application No. 61/099,001, filed on Sep. 22, 2008.

(51) Int. Cl. H01L 27/06; H01G 4/008; B05D 5/12

(52) U.S. Cl. 257/296; 361/305; 427/79; 257/532; 257/E27.016

(57) ABSTRACT

A method is disclosed for manufacturing SrₓTi_{y}O₃ based metal-insulator-metal (MIM) capacitors using a low temperature Atomic Layer Deposition (ALD) process. Preferably TiN is used to form the bottom electrode. The Sr/Ti ratio in the SrₓTi_{y}O₃ dielectric layer of the capacitor can be varied to tune the electric properties of the capacitor. The dielectric constant and the leakage current of the SrₓTi_{y}O₃ dielectric layer decrease monotonously with the Sr content of this SrₓTi₁₋ₓO₃ dielectric layer. By increasing the Sr content at the interface between the SrₓTi_{y}O₃ dielectric layer and the TiN bottom electrode, the interfacial equivalent-oxide thickness (EOT) can be further reduced.

### RELATED APPLICATION

This application claims priority under 35 U.S.C. §119(e) to U.S. Provisional Patent Application Ser. No. 61/099,001, filed on Sep. 22, 2008, the full disclosure of which is incorporated herein by reference.

### FIELD OF THE DISCLOSURE

The present disclosure relates to capacitive structures whereby an insulating material is sandwiched between a metal top electrode and a metal bottom electrode. These capacitive structures are also known as MIM (metal-insulator-metal) capacitive structures. In particular the present disclosure relates to volatile memory cells comprising such MIM capacitive structures.

### BACKGROUND

Future dynamic random access memory (DRAM) nodes require Metal-Insulator-Metal capacitors (MIMcaps) having Equivalent Oxide Thicknesses (EOT) less than 0.5 nm and low leakage current densities, i.e. less than 10⁻⁷ A/cm².

Typical high dielectric constant (K) materials, such as ZrO₂/Al₂O₃/ZrO₂, used nowadays in fabrication lines are no longer considered as potential solutions for future DRAM nodes because of their too low dielectric constant (K˜40).

Hence, various materials systems are being explored to manufacture such MIM capacitors, in particular for use in a DRAM memory cell. Among various materials, SrₓTi_{y}O₃ (STO) appears as a promising candidate. The interest in this material can be explained both by its good dielectric characteristics (K˜150-300) and also by recent improvements in the atomic layer deposition (ALD) process enabling the deposition of conformal STO thin films at a reasonably low processing temperature (≦300° C.) suitable for high aspect ratio DRAM applications.

U.S. Pat. No. 7,108,747 discloses an Atomic Layer Deposition (ALD) process for producing SrTiO₃ thin films. United States patent application US2006/0219157 also discloses an Atomic Layer Deposition (ALD) process for producing titanium containing oxide thin films.

Recently, ALD SrₓTi_{y}O₃ using Sr(thd)₂ as the Sr precursor has been reported with promising results on noble like metal electrodes such as Ru and Pt. Oh Seong Kwon et al discloses in “Atomic Layer Deposition and Electrical Properties of SrTiO₃ Thin films Grown using Sr (C₁₁H₁₉O₂)₂, Ti (Oi-C₃H₇)₄ and H₂O” in Journal Of electrochemical Society 154 (6), G127-G133 (2007) a method for growing SrTiO₃ (STO) thin films by means of Atomic Layer Deposition (ALD) thereby using particular precursors. The thin dielectric film is grown on a Ru bottom electrode. However, the processes used required either high deposition temperatures (>350° C.) and/or post-deposition anneals in an oxidizing ambient, making them incompatible with a TiN bottom electrode. Moreover metal such as Ru and Pt are not compatible with state-of-the-art logic semiconductor processing.

Therefore there is a need to manufacture a metal-insulator-metal capacitor structure having an EOT of 0.5 nm or less and a leakage current less than 5×10⁻⁷ A/cm².

There is a need to manufacture such capacitor using process steps and materials that are compatible with standard logic semiconductor processing.

There is a need to form such the insulating layer of such capacitor at temperatures equal to or less than 300° C.

There is a need to manufacture such a capacitor having a reduced EOT of the interfacial oxide between the insulating layer and the bottom electrode.

### SUMMARY

A metal-insulator-metal capacitor is disclosed comprising a stack of a bottom electrode, an insulating layer and a top electrode, whereby the insulating layer is a [Ba_{1-q}Sr_{q}]ₓTi_{y}O_{z} oxide, with q, x, y, z being integers, 0<q<1 and (x/y)>(1/1). Preferably this insulating layer is [Ba_{1-q}Sr_{q}]ₓTi_{y}O_{z} oxide. If q=1, this insulating layer is a SrₓTi_{y}O_{z} oxide. If q=0, this insulating layer is a BaₓTi_{y}O_{z} oxide. The [Ba_{1-q}Sr_{q}]/Ti ratio (x/y) is larger than 1, and preferably between (1/1)<(x/y)<(4/1). The bottom electrode of this metal-insulator-metal capacitor can comprises Ti, preferably consist of TiN.

A DRAM memory cell is disclosed comprising a metal-insulator-metal capacitor and a selection device. The metal-insulator-metal capacitor comprises a stack of a bottom electrode, an insulating layer and a top electrode, whereby the insulating layer is a [Ba_{1-q}Sr_{q}]ₓTi_{y}O_{z} oxide, with q, x, y, z being integers, 0<q<1 and (x/y)>(1/1). Preferably this insulating layer is [Ba_{1-q} Sr_{q}]ₓTi_{y}O₃ oxide. If q=1, this insulating layer is a SrₓTi_{y}O_{z} oxide. If q=0, this insulating layer is a BaₓTi_{y}O_{z} oxide. The [Ba_{1-q}Sr_{q}]/Ti ratio (x/y) is larger than 1, and preferably between (1/1)<(x/y)<(4/1). The bottom electrode of this metal-insulator-metal capacitor can comprise Ti and preferably consist of TiN.

A method for manufacturing a metal-insulator-metal capacitor is disclosed, the method comprising forming a bottom electrode, forming an insulating layer on the bottom electrode, and forming a top electrode on the insulating layer, whereby the insulating layer is a [Ba_{1-q}Sr_{q}]ₓTi_{y}O_{z} oxide, with q, x, y, z being integers, 0<q<1 and (x/y)>(1/1). Preferably this insulating layer is [Ba_{1-q}Sr_{q}]ₓTi_{y}O₃ oxide. If q=1, this insulating layer is a SrₓTi_{y}O_{z} oxide. If q=0, this insulating layer is a BaₓTi_{y}O_{z} oxide. The [Ba_{1-q} Sr_{q}]/Ti ratio (x/y) is larger than 1, and preferably between (1/1)<(x/y)<(4/1). The bottom electrode of this metal-insulator-metal capacitor can comprise Ti and preferably consist of TiN. The insulating layer can be formed by Atomic Layer Deposition. Preferably the insulating layer is formed directly on the bottom electrode (TiN), and the method further comprises performing a anneal step on the as-formed insulating layer thereby bringing the insulating layer into the crystalline perovskite phase.

### BRIEF DESCRIPTION OF THE DRAWINGS

FIG. 1 shows a schematic of a MIM capacitor according to the disclosure.

FIG. 2 shows a DRAM memory cell containing a transistor and a MIM capacitor according to the disclosure.

FIGS. 3a-c illustrates, by means of schematic cross-sectional views of process steps, a method for manufacturing MIM capacitor according to the disclosure.

FIG. 4 shows a schematic of the pulse sequence of the ALD STO deposition process for manufacturing MIM capacitor according to a first exemplary embodiment.

FIG. 5 shows the Sr/Ti atomic ratio x/y, determined by RBS, as function of the Sr/Ti pulse ratio (n*/m*) according to a first exemplary embodiment.

FIG. 6 shows high resolution RBS profiles of STO films for the three compositions illustrated by FIG. 5: standard composition (diamonds), Ti-rich (squares), Sr-rich (triangles), according to a first exemplary embodiment.

FIG. 7 shows the perovskite crystallization temperature (° C.) as function of the film thickness (nm), for STO films having one of the three compositions illustrated by FIG. 5, according to a first exemplary embodiment.

FIG. 8 shows XRD spectra of STO films, having one of the three compositions illustrated by FIG. 5, on a ALD TiN bottom electrode: as-deposited (full line), after anneal to 600° C. (open circles) and after high temperature anneal (closed circles), according to a first exemplary embodiment.

FIG. 9 shows capacitance-voltage (C-V) and conductance-voltage (G-V) curves of STO films having either the crystalline standard composition or crystalline Sr-rich composition as illustrated by FIG. 5 for two different STO film thicknesses, according to a first exemplary embodiment.

FIG. 10 shows the EOT-thickness (nm) as function of the physical thickness (nm) for STO films having the Std. Comp., as illustrated in FIG. 5, when deposited on a MOCVD TiN bottom electrode after various thermal treatments, according to a first exemplary embodiment.

FIG. 11 shows the capacitance (C) (full symbols) and conductance G (open symbols) as function of the capacitor area (um2) for STO films, having one of the three compositions illustrated by FIG. 5, on an ALD TiN bottom electrode: standard composition (diamonds), Ti-rich (squares), Sr-rich (triangles), according to a first exemplary embodiment.

FIG. 12 shows leakage current density (Jg) vs. voltage (V) characteristics for crystallized STO films, having one of the three compositions illustrated by FIG. 5, on a ALD TiN bottom electrode: standard composition (diamonds), Ti-rich (squares), Sr-rich (triangles), according to a first exemplary embodiment.

FIG. 13 shows the EOT thickness as function of the physical thickness for a STO film formed on an ALD TiN bottom electrode, the STO film having either the standard composition or the Sr-rich composition as illustrated by FIG. 5, according to a first exemplary embodiment.

FIG. 14 shows the leakage current density (Jg) vs. voltage (V) characteristic for 8 nm crystallized Sr-rich STO film, as illustrated by FIG. 5, on a ALD TiN bottom electrode: standard composition (diamonds), Ti-rich (squares), Sr-rich (triangles), according to a first exemplary embodiment.

FIG. 15 shows the leakage current density (Jg) vs. voltage (V) characteristics for crystallized STO films, having either the standard composition or the Sr-rich composition as illustrated by FIG. 5, for different types of bottom electrodes: W, ALD TiN, MOCVD TiN and for different thermal treatments, according to a first exemplary embodiment.

FIG. 16 shows high resolution RBS profiles of SrₓTi_{y}O₃ films for the various compositions of the STO film according to a second exemplary embodiment.

FIG. 17 shows temperature of crystallization into perovskite SrₓTi_{y}O₃ phase as a function of STO film composition and thickness according to a second exemplary embodiment. The crystallization temperatures are extracted from IS-XRD measurements.

FIG. 18 shows θ-2θ XRD diagrams of 10 nm SrₓTiyO₃ films deposited on a TiN bottom electrode with various compositions after high temperature anneal according to a second exemplary embodiment.

FIG. 22 shows XRD diagrams focused on the (200) Bragg peak of 10 nm Sr-rich (3:1) SrₓTi_{y}O₃ films as-deposited, after anneal at 600° C. and after high temperature anneal according to a second exemplary embodiment. As a comparison, the position of reported cubic SrTiO₃ (200) peak is given.

FIG. 20 shows the equivalent oxide thickness (EOT) vs. physical thickness of as deposited (amorphous) SrₓTi_{y}O₃ films with various compositions according to a second exemplary embodiment. The bottom (respectively top) electrode was TiN (respectively Pt).

FIG. 21 shows the leakage current density (J_{g}) vs. applied voltage (V) characteristics of 16 nm as deposited (amorphous) SrₓTi_{y}O₃ films with various compositions according to a second exemplary embodiment. The delay time was 10 ms.

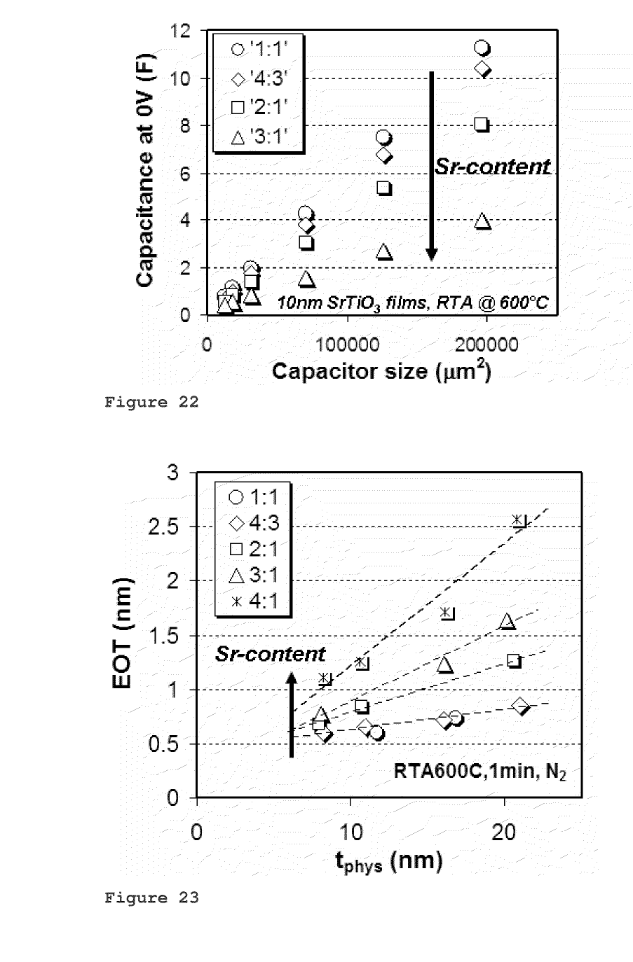

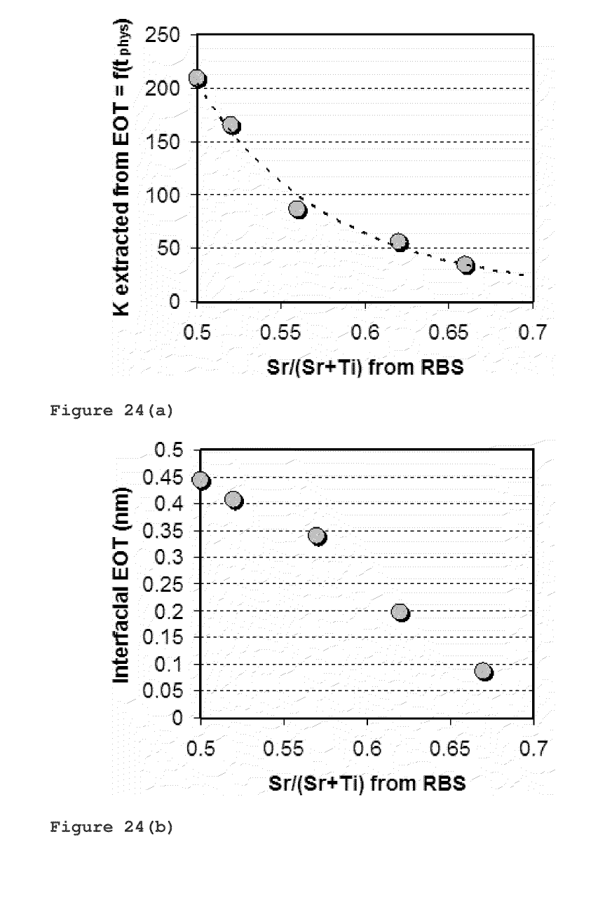

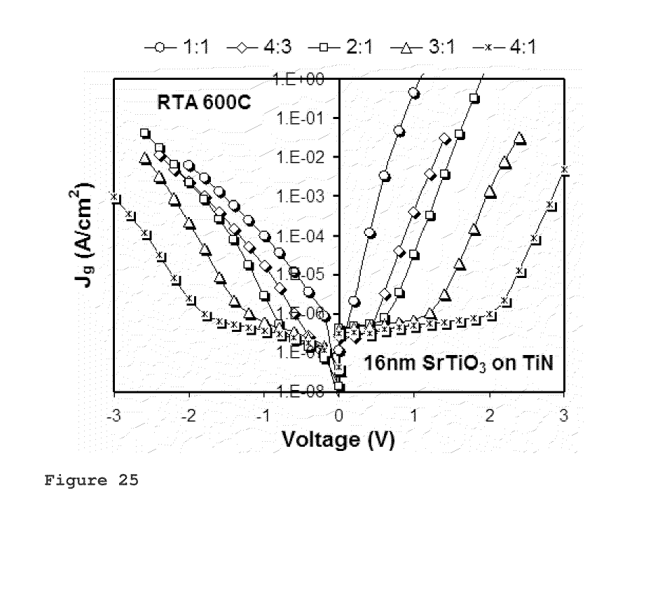

FIG. 22 shows the capacitance (measured at 0 V, 1 kHz) vs. capacitor area of 10 nm crystalline SrₓTi_{y}O₃ films with various compositions according to a second exemplary embodiment. The crystallization anneal was performed at 600° C. for 1 min in N₂. The bottom (respectively top) electrode was TiN (respectively Pt).

FIG. 23 shows the equivalent oxide thickness (EOT) vs. physical thickness of crystalline SrₓTi_{y}O₃ films with various compositions according to a second exemplary embodiment. The crystallization anneal was performed at 600° C. for 1 min in N₂. The bottom (respectively top) electrode was TiN (respectively Pt).

FIG. 24 shows the evolution of the dielectric constant (a) and interfacial EOT (b) as a function of the STO film composition according to a second exemplary embodiment. The K and interfacial EOT values are extracted form linear fitting of the EOT vs. physical thickness data presented in FIG. 23.

FIG. 25 shows leakage current density (J_{g}) vs. applied voltage (V) characteristics of 16 nm crystalline SrₓTi_{y}O₃ films with various compositions according to a second exemplary embodiment. The delay time was 550 ms. The crystallization anneal was performed at 600° C. for 1 min in N₂. The bottom (respectively top) electrode was TiN (respectively Pt).

### DETAILED DESCRIPTION

The drawings described are only schematic and are non-limiting. In the drawings, the size of some of the elements may be exaggerated and not drawn on scale for illustrative purposes. The dimensions and the relative dimensions do not necessarily correspond to actual reductions to practice of the disclosure.

Furthermore, the terms first, second, third and the like in the description and in the claims, are used for distinguishing between similar elements and not necessarily for describing a sequential or chronological order. The terms are interchangeable under appropriate circumstances and the embodiments of the disclosure can operate in other sequences than described or illustrated herein.

Moreover, the terms top, bottom, over, under and the like in the description and the claims are used for descriptive purposes and not necessarily for describing relative positions. The terms so used are interchangeable under appropriate circumstances and the embodiments of the disclosure described herein can operate in other orientations than described or illustrated herein.

The term “comprising”, used in the claims, should not be interpreted as being restricted to the means listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present disclosure, the only relevant components of the device are A and B.

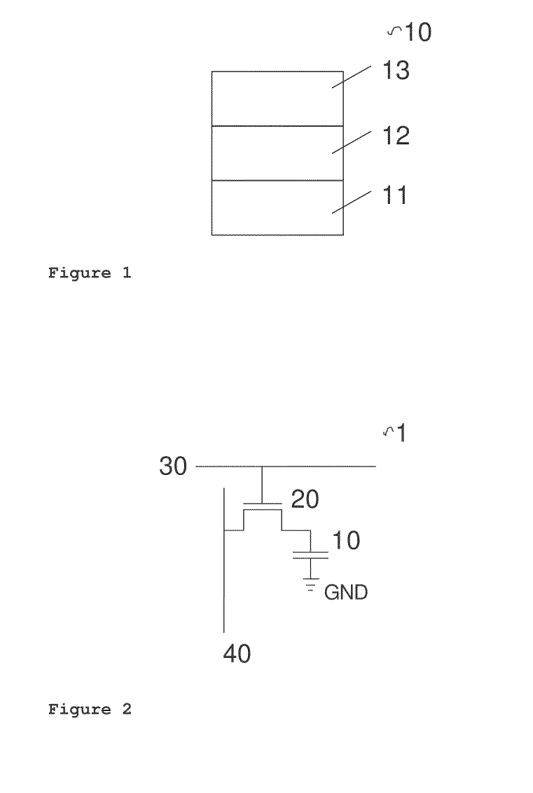

MIM capacitors 10 are formed by sandwiching a layer 12 of insulating material between a metal top electrode 13 and a metal bottom electrode 11 as shown in FIG. 1. The bottom electrode 11 is the layer in direct physical contact with the insulating layer 12. Other layers can be present underneath the bottom electrode 11 to provide a good electrical contact to other devices 20 and/or to provide a diffusion barrier. The insulating layer should be formed in a conformal way to provide good step coverage over the underlying bottom electrode 11. Such capacitors 10 are used inter alia to form dynamic random access memory cells (DRAM). DRAM cells are preferably manufactured using materials, in particular metals, compatible with the processing of logic semiconductor devices such as transistors to allow processing of logic devices and MIM capacitors on the same chip. These materials are available at low-cost and manufacturing-friendly

An elementary DRAM memory cell 1 consists of a selection element 20, such as transistor, and capacitor 10 as shown in FIG. 2. The transistor 20 controls the access to the capacitor 10 as this capacitor 10 is connected between one junction of the transistor 10 and ground GND. In such a memory cell information is saved by storing the corresponding amount of charge on the capacitor 10. Typically these memory cells are arranged in a matrix configuration whereby a word line 30 connects the gate of each transistor 10 in the same row, while a bit line 40 connects the other junction each transistor 10 in the same column.

The material of the insulating layer 12 is selected to have a high value of its relative dielectric constant k and a low leakage current such that information can be temporally stored with limited amount of charge. The high relative dielectric constant k of the insulating layer allows obtaining a thin electrical Equivalent Oxide Thickness (EOT) for a physical thicker layer thereby offering a high capacitance value per unit square. With high-k dielectric is meant a dielectric material having a relative dielectric constant k larger than 1, typically larger than 10.

The metals of the top 13 and bottom 11 electrodes are selected to help reducing the overall series resistance of the memory cell 1. The process for forming the insulating layer 12 must be compatible with the material used to form the bottom electrode 11. High thermal budgets used to form the insulating layer 12 either during deposition or during post-deposition anneal steps might impact the physical and electrical properties of the bottom electrode 11. Also the ambient in which the insulating layer 12 is formed might influence physical and electrical properties of the bottom electrode 11.

A SrₓTi_{y}O_{z} (STO) based Metal-Insulator-Metal (MIM) capacitor 10 is disclosed having an EOT of less than 0.5 nm and a leakage current less 5×10⁻⁷ A/cm², preferably less than 1×10⁻⁷ A/cm², when 1V is applied between the top 13 and bottom 11 electrode. X, y and z are integers, whereby z is preferably 3 and x/y>1.

The as-deposited layer thickness of this STO insulating layer 12 is in the range of 5 to 30 nm. The Sr-to-Ti ratio x/y>1, preferably between (1/1)<x/y<(4/1).

In a metal-insulator-metal capacitor 10 according to this disclosure, the insulating material 2 as deposited is a strontium-rich SrₓTi_{y}O_{z} material with x, y, z, being integers. With Sr-rich SrₓTi_{y}O_{z} is meant an oxide whereby the Sr-to-Ti ratio x/y is greater than the stoichiometric ratio, i.e. the Sr-to-Ti ratio x/y is greater than 1. FIG. 5 illustrates examples of such non-stoichiometric SrₓTi_{y}O_{z} material.

In metal-insulator-metal capacitors 10 according to this disclosure SrₓTi_{y}O_{z} grains with a Sr content in excess of the stoichiometric ratio x/y=1 may be present in the insulating layer 12. These Sr-rich grains may be distributed over the area of this layer 12 such that leakage paths between the top electrode 13 and the bottom electrode 11 are prevented or at least the number of such leakage paths is reduced compared to a stoichiometric SrTiO₃ insulating layer. As these Sr-rich grains may have a smaller diameter compared to a stoichiometric SrₓTi_{y}O_{z} insulating layer 12, the non-stoichiometric layer of this disclosure may show less cracks.

In metal-insulator-metal capacitors 10 according to this disclosure the interface between the Ti-containing bottom electrode 11 and the SrₓTi_{y}O_{z} insulating layer 12 is essentially free from titanium-oxide such that the Ti-containing bottom electrode 11 is in direct physical contact with this insulating layer 12. As titanium-oxide might be present in different crystal orientations on top of the Ti-containing bottom electrode, growing the SrₓTi_{y}O_{z} having the required properties on top of such titanium-oxide is cumbersome.

The SrₓTi_{y}O_{z} based insulating layer 12 of his MIM capacitor 10 is sandwiched between a bottom electrode 11 and a top electrode 13 as shown in FIG. 1. The insulator 12 of this MIM capacitor 10 comprises an oxide of strontium and titanium and the metal bottom electrode 11 comprises Ti. The metal top electrode 13 can be formed from Pt or other metals used in the art to form a top electrode for a MIM capacitor 10.

In a preferred embodiment this insulator 12 consists of an oxide of strontium and titanium and the metal bottom electrode 11 consists of TiN.

A method is disclosed for manufacturing SrₓTi_{y}O₃ based Metal-Insulator-Metal (MIM) capacitors having an EOT of less than 0.5 nm and a leakage current less than, preferably less than 5×10⁻⁷ A/cm².

The method comprises forming the insulating layer using a low temperature Atomic Layer Deposition (ALD) process. Preferably this ALD process employs an Sr(t-Bu₃ Cp)₂ based precursor system. The ALD process is performed at temperatures less than 300° C., preferably 250° C. This method further requires optimizing the ALD deposition variables, the insulator layer composition and the post-insulator layer deposition processing.

This manufacturing method allows the use of low-cost, manufacturable-friendly TiN bottom electrodes. By varying the Sr/Ti ratio in the SrₓTi_{y}O_{z} dielectric layer of the capacitor, the electric properties of the capacitor can be tuned as film crystallization temperature, its texture and morphology strongly depends on this ratio. The dielectric constant and the leakage current decrease monotonously with the Sr content in the Sr-enriched insulating layer 12. The intercept of the EOT vs. physical thickness plot further indicates that increasing the Sr-content at the film interface with the bottom TiN would result in lower interfacial equivalent-oxide thickness (EOT).

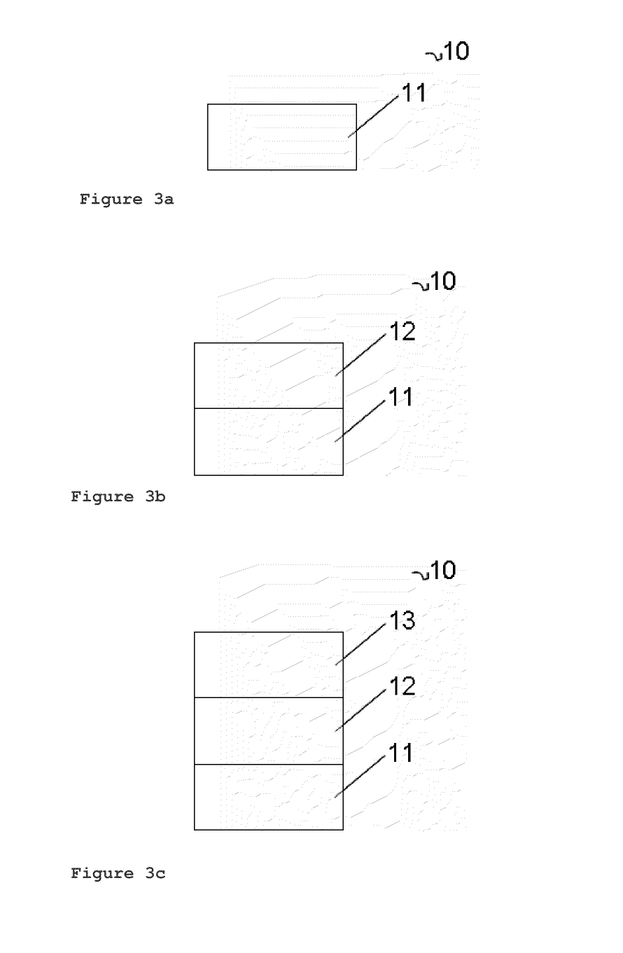

A method is disclosed, illustrated by FIGS. 3a-c, for forming such a metal-insulator-metal capacitor 10 whereby the insulator 12 comprises an oxide of strontium and titanium and the metal bottom electrode 11 comprises Ti. The method comprises: forming a bottom electrode 11 comprising titanium (FIG. 3a), forming on the bottom electrode 11 an insulating layer 12 comprising an oxide of strontium and titanium (FIG. 3b), and forming on the insulating layer 12 a top electrode 13 whereby the top electrode 13 is electrically isolated from the bottom electrode 11 (FIG. 3c).

In a preferred embodiment a method is disclosed, illustrated by FIGS. 3a-c, for forming such metal-insulator-metal capacitor 10 whereby the insulator 12 consists of an oxide of strontium and titanium and the metal bottom electrode 11 consists of TiN. The method comprises: forming a bottom electrode 11 consisting of TiN (FIG. 3a), forming on the bottom electrode 11 an insulating layer 12 consisting of an oxide of strontium and titanium (FIG. 3b), and forming on the insulating layer a top electrode 13 whereby the top electrode 13 is electrically isolated from the bottom electrode 11 (FIG. 3c). The insulating layer 12 is in direct physical contact with the bottom electrode 11 and the top electrode 13 is in direct physical contact with the insulating layer 12.

Prior to the step of forming the metal top electrode 13 a thermal step can be performed to crystallize the insulating layer 12. In case of a Sr-rich SrₓTi_{y}O_{z} oxide a crystalline oxide can be obtained at temperatures below 600° C., even below 550° C., whereby the high-k perovskite crystalline phase is obtained. This crystallization step is preferably performed in a temperature range between 500° C. and 600° C., more preferably in a temperature range between 530° C. and 570° C., typically at a temperature of about 550° C.

The bottom electrode 11 containing Ti can be formed by Atomic Layer Deposition (ALD), by Metal-Organic Chemical Vapor Deposition (MOCVD), by Physical Vapor Deposition (PVD) or by other techniques known in the semiconductor process technology.

The insulating layer 12 is formed in a low-oxygen ambient, preferably a non-oxidizing ambient, such that the underlying Ti-containing bottom electrode 11 remains essentially oxide-free during the insulating layer forming process. This insulating layer 12 can be formed using Atomic Layer Deposition (ALD) with selected precursors allowing the formation of the insulating layer 12 at lower temperatures, i.e. between 200° C. and 300° C. and in a low oxygen or oxygen-free ambient. This precursor is preferably a Sr(t-Bu₃ Cp)₂ based precursor system.

U.S. Pat. No. 7,108,747 discloses an Atomic Layer Deposition (ALD) process for producing SrTiO₃ thin films. United States patent application US2006/0219157 also discloses an Atomic Layer Deposition (ALD) process for producing titanium containing oxide thin films. Both are incorporated by reference in their entirety.

The insulating material 12 as deposited is a strontium-rich SrₓTi_{y}O_{z} material with x, y, z, being integers. With Sr-rich SrₓTi_{y}O_{z} is meant an oxide whereby the Sr-to-Ti ratio x/y is greater than the stoichiometric ratio, i.e. the Sr-to-Ti ratio x/y is greater than 1.

During the step of depositing the SrₓTi_{y}O_{z} insulating layer 12 the ratio Sr-to-Ti x/y can be kept higher than the stoichiometric ratio x/y=1. Optionally this Sr-to-Ti ratio x/y can be kept substantially equal to the stoichiometric ratio 1, while only during a part of the deposition process this Sr-to-Ti ratio x/y is set higher than the stoichiometric value 1.

In a preferred embodiment a method is disclosed for forming such metal-insulator-metal capacitor 10 whereby the insulator 12 consists of an oxide of strontium and titanium and the metal bottom electrode 11 consists of TiN. The method comprises: forming a bottom electrode 11 consisting of titanium nitride, forming on the bottom electrode 11 an insulating layer 12 consisting of an oxide of strontium and titanium, and forming on the insulating layer 12 a top electrode 13 whereby the top electrode 13 is electrically isolated from the bottom electrode 11.

The metal-insulator-metal capacitor 10 according to this patent application shows an Electrical Equivalent Oxide Thickness (EOT) of less than 0.5 nm while the leakage current through the insulating layer 12 is less than 500 nA/cm³ when 1V is applied between the top 13 and bottom 11 electrode.

### Example 1

### Experimental Details

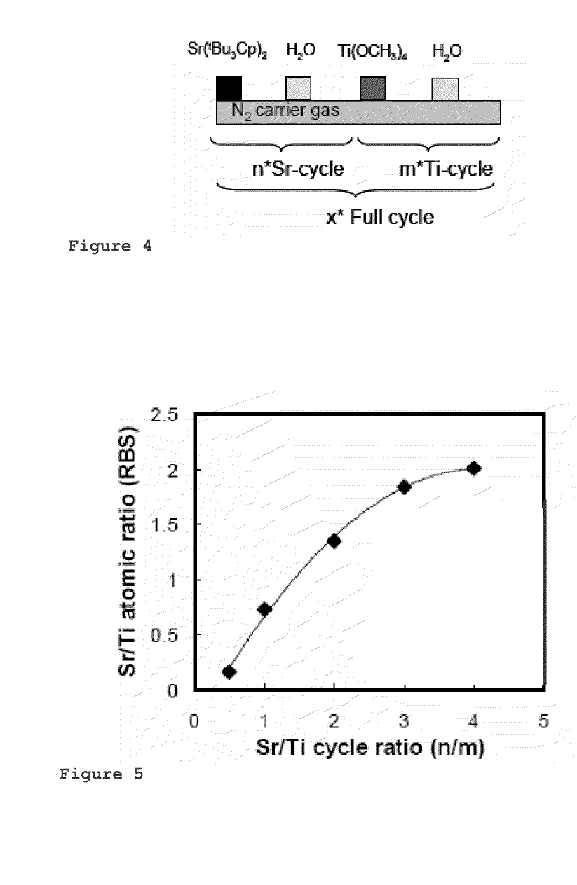

STO layers were deposited by Atomic Layer Deposition (ALD) in a cross-flow ASM Pulsar® 2000 reactor, at reactor temperatures in the 250° C.-300° C. range. The precursors were Sr(t-Bu3 Cp)2, H2O, and Ti(OCH3)4. In order to make a layer having a predetermined thickness the full cycle has to be repeated a number x*, while within each full cycle the number n* of Sr precursor pulses and the number m* of Ti precursor pulses can be selected in view of the desired Sr/Ti ratio within that full cycle as illustrated by FIG. 4. By changing the Sr-precursor and the Ti-precursor pulse sequence, ALD allows the growth of a wide compositional variety of STO films from pure TiO2 to Sr-rich, with straight forward composition tuning. FIG. 2 shows the Sr/Ti atomic ratio x/y as determined by Rutherford Backscattering (RBS) as function of the Sr/Ti pulse cycle ratio n*/m* thereby referring to the sequence illustrated in FIG. 4. A pulse cycle ratio n*/m* of about 1.5 corresponds to a stoichiometric SrTiO₃ with x=y=1 and z=3.

In ALD, the STO growth is determined by self-limiting surface reactions, guaranteeing conformal deposition of STO in high aspect ratio structures which is required for advanced DRAM structures. STO films 12 in the 7-30 nm range were grown respectively on ALD TiN, MOCVD TiN or W bottom electrodes 11. Three different Sr:Ti composition atomic ratios x/y were studied, a “standard composition” close to stoichimoetric atomic ratio (x/y˜1), a Ti-rich composition (x/y˜0.2) and a Sr-rich composition (x/y˜1.5).

### Physical Analysis

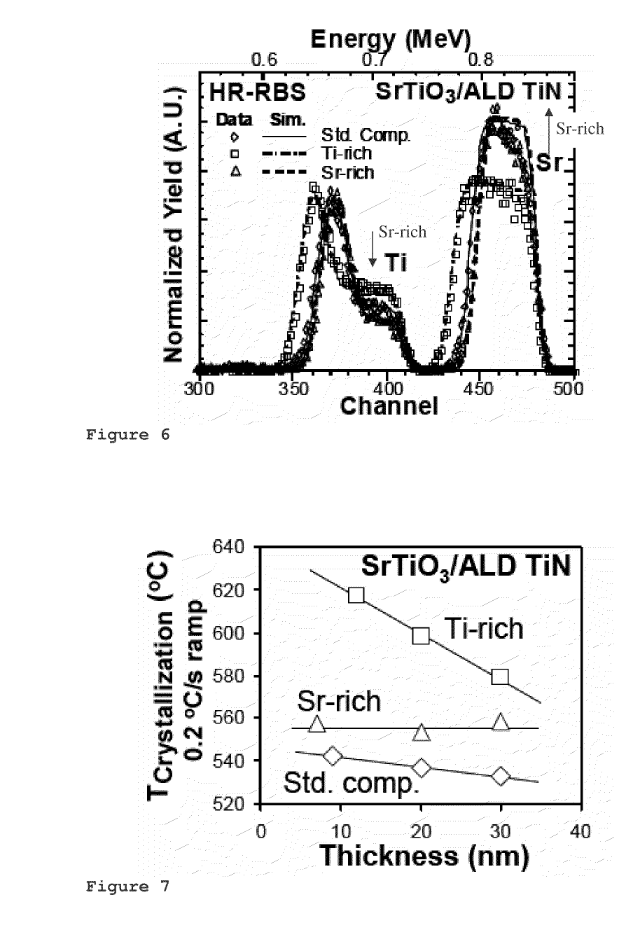

FIG. 6 shows examples of high resolution Rutherford BackScattering (RBS) profiles of STO films 12 on a ALD TiN bottom electrode 11 for the three compositions: standard composition (Std Comp) (diamonds), Ti-rich (squares) and Sr-rich (triangles). As-deposited STO films were amorphous.

Careful characterization of the STO crystallization behavior of these three STO film 12 compositions was achieved by in-situ XRD measurement during ramp anneals in a He ambient whereby the film was annealed in the ALD chamber. All three film composition crystallized into the high-k perovskite STO phase at temperatures in the 540-620° C. range. Crystallization of sub-10 nm Std. Comp. (x/y˜1) and Sr-rich (x/y˜0.2) films 12 after ex-situ 550° C. 1 min anneal in N2 was also verified by cross-sectional TEM. FIG. 7 shows the temperature of the 3 STO film 12 types, formed on an ALD TiN bottom electrode 11, as function of the film thickness at which temperature the STO film crystallizes into the perovskite phase. The temperature was ramped at 0.2° C./sec. The crystallization temperature was higher for the Ti-rich films (x/y˜0/2), especially for the thinner films.

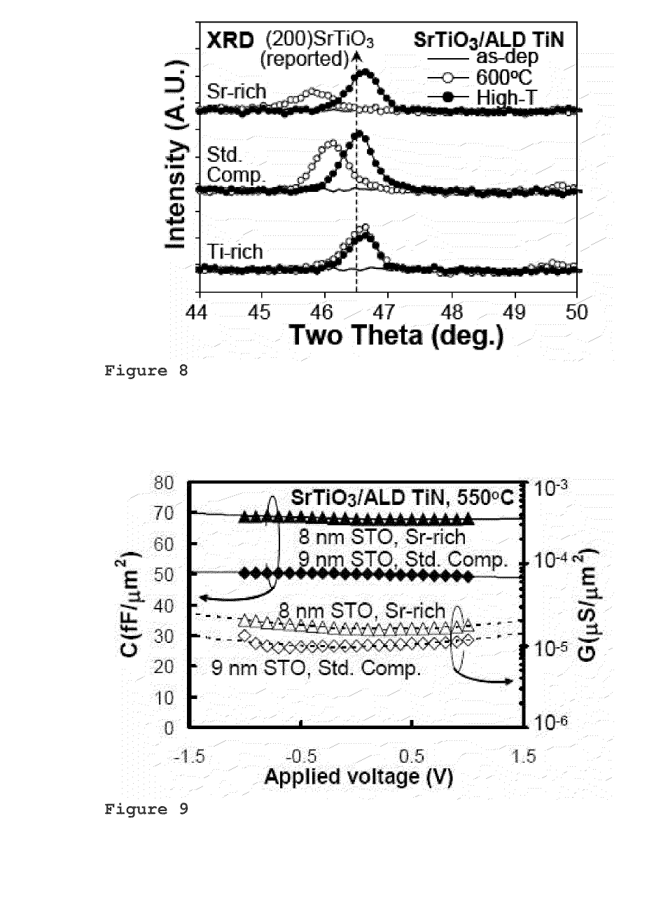

TEM analysis showed, in agreement, that 14 nm Ti-rich films were still mostly amorphous after 550° C. anneal. STO peak-positions for Sr-rich films (x/y˜1.5) after anneal to 600° C. were found to be shifted respect to reported bulk, i.e. very thick STO layers, STO values, but reached the bulk values with higher T annealing. FIG. 8 shows the XRD spectra of three STO film types deposited on ASD TiN bottom electrode 11. The shift is clearly for the thicker Sr-rich STO film, with bulk STO values achieved above 800° C. This suggests Sr may be in solution in STO after low temperature crystallization anneals and expelled out of STO grains at higher temperatures. The RBS data in FIG. 6 suggests excess Sr may be preferentially close to the bottom TiN interface.

### Electrical Evaluation

In order to perform an electrical evaluation of three STO film types, after annealing the insulating STO layer 12 into the crystalline perovskite phase, a PT top electrode 13 on the stack of the respective crystalline STO layer 12/TiN bottom electrode 11.

FIG. 9 presents typical C-V, G-V curves measured on these STO 12/ALD TiN 11 films, with the STO film 12 having either the standard composition (x/y˜1) or the Sr-rich composition (x/y˜1.5), after Rapid Thermal Anneal (RTA) at 550° C. for 60 sec in N2. Flat C-V characteristics with high capacitance densities are observed while conductance values remain low.

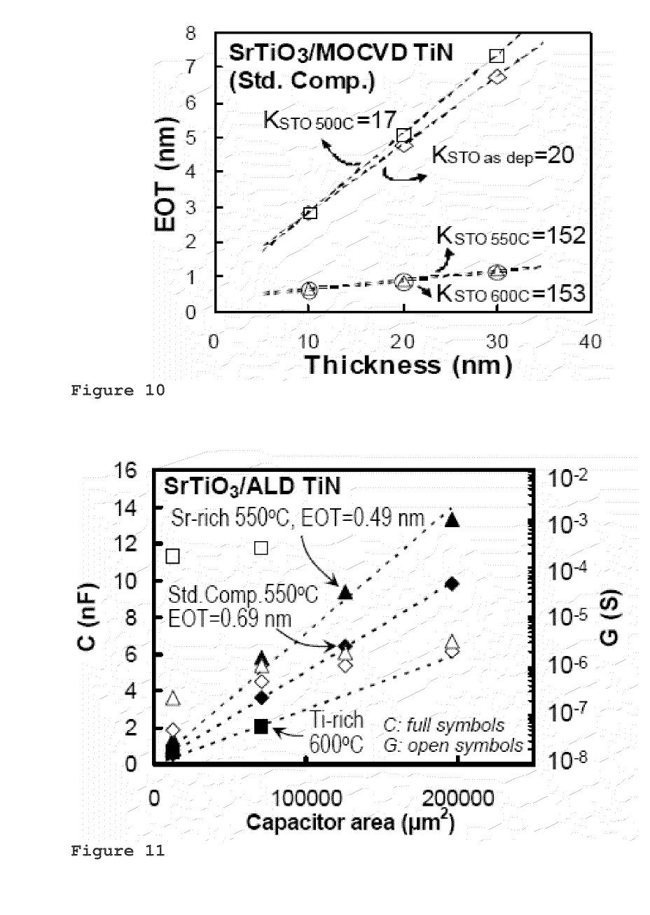

The impact of crystallization on the electrical properties of STO films on a MOCVD TiN bottom electrode 11 is clearly depicted in FIG. 10 showing the relationship between the EOT thickness (nm) and the physical thickness (nm) for a STO film 12 having the standard composition (Std. Comp.: x/y˜1) as function of the crystallization anneal step: no anneal i.e. as deposited, anneal 500° C., anneal 550° C. and anneal at 600° C. Typical K values obtained for crystalline STO films with Std. Comp. are ˜150. In agreement with the outcome of the in situ XRD measurements illustrated by FIG. 8, an anneal at 500° C. is not sufficient to crystallize Std. Comp. STO films which will show a K value comparable to amorphous films (˜20). Similar results were obtained for these STO films when an ALD TiN bottom electrode 12 was used.

FIG. 11 shows that measured capacitance C and conductance G of annealed crystalline STO films 12 according to FIG. 5, sandwiched between an ALD TiN bottom electrode 11 and a Pt top electrode 13. The Std Comp and Sr rich STO film were annealed at 550° C., while the Ti rich STO film was annealed at 600° C. in line with the discussion above regarding FIGS. 4 and 5. For each type of STO film 12, the capacitance C scales linearly with the capacitor area. Extracted values for the EOT are as low as 0.49 nm for a 7.5 nm Sr-rich film (x/y˜1.5) and 0.69 nm for a 9 nm Std. Comp. film (x/y˜1) while the conductance remains low, i.e. exhibiting a low leakage current.

FIG. 12 shows leakage current density Jg-voltage V characteristics for crystallized STO films, having one of the three compositions illustrated by FIG. 5, on a ALD TiN bottom electrode: standard composition (diamonds), Ti-rich (squares), Sr-rich (triangles). For the Ti-rich (x/y˜0.2) STO film it was difficult to extract the EOT due to the high conductivity/high leakage observed in those films as can be seen in FIGS. 8 and 9.

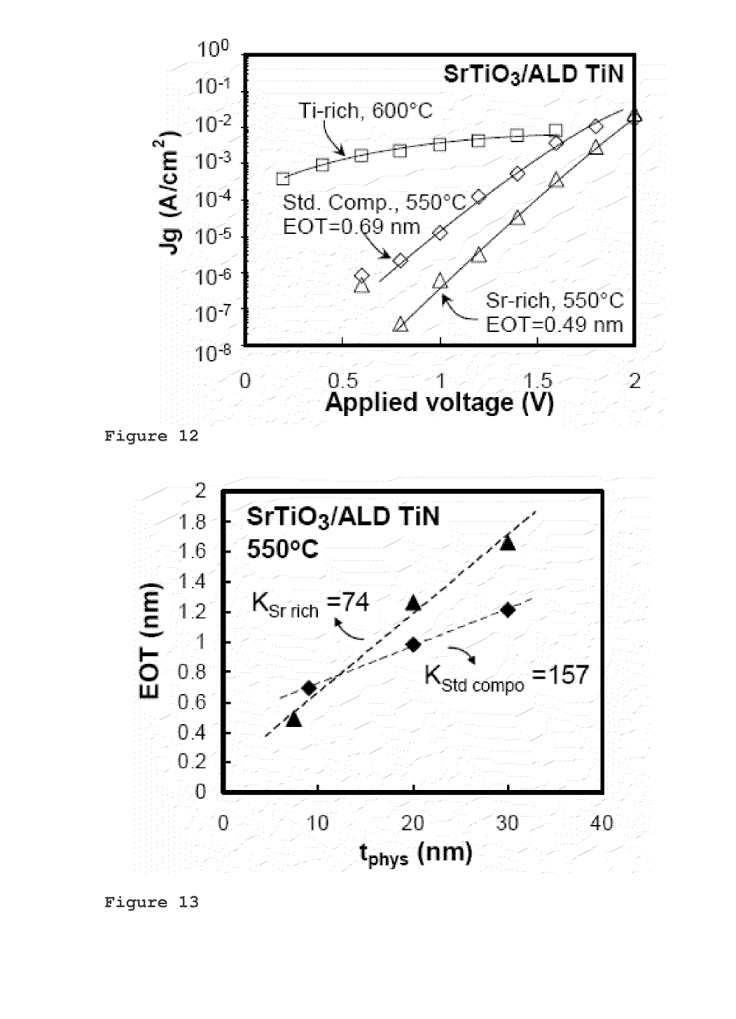

FIG. 13 further compares the electrical characteristics of crystallized STO films with standard (x/y˜1) and Sr-rich (x/y˜1.5) compositions as shown in FIG. 5. A linear relationship between EOT and physical thicknesses is observed, from which K values can be extracted for both compositions. Sr-rich samples show lower K and lower leakage than Std. Comp. films. Despite lower K values, for thin films (tphys<10 nm), lower EOTs can be achieved for Sr-rich films which is attributed to a better interface with the underlying TiN bottom electrode 11.

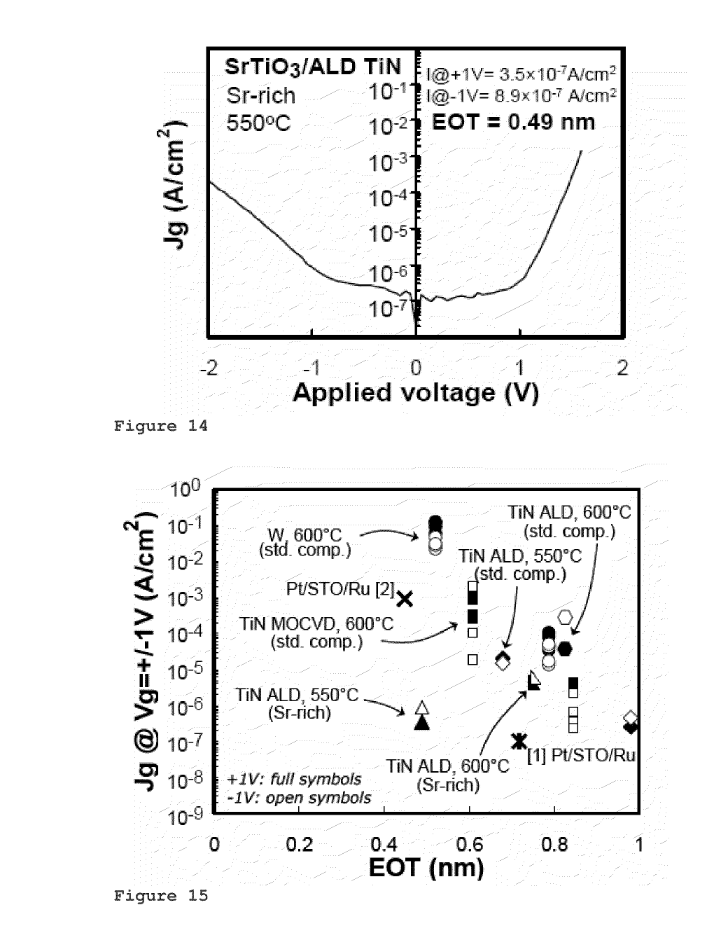

Typical leakage current density Jg-V behavior of a MIMcap device 10 composed of a Pt top electrode 13/a crystallized Sr-rich STO insulating layer 12/a TiN bottom electrode 11, whereby the insulating layer had EOT of 0.49 nm is presented in FIG. 14. An excellent low leakage behavior is observed, with Jg(+1V)=3.5×10−7 A/cm2 and Jg(−1V)=8.9×10−7 A/cm2 which are the lowest leakage values reported so far for STO with ˜0.5 nm EOT.

Conductive AFM measurements were performed to understand, at a microscopic scale, the leakage paths in the STO films. From these measurements it is concluded that the leakage conduction is through the bulk of grains and follows the topography whereby a higher topography corresponding to a higher leakage. If one compares the density of the leakage spots as obtained by these conductive AFM measurements (Vg=3.2V) of STO films (tphys<10 nm) with Std. (x/y˜1) and Sr-rich (x/y˜1.5) compositions, one can see that the density of leakage spots is higher for the Std. Comp., in agreement with the I-V curves shown in FIG. 12.

Leakage density values at ±1V are presented as a function of EOT in FIG. 15 for crystallized Std. (x/y˜1) and Sr-rich (x/y˜1.5) STO films 12 deposited on TiN (ALD, MOCVD) and W bottom electrodes 11 and after different thermal treatments, showing improvement for films on TiN over recent published data on Ru. 550° C. seems to be the optimal anneal temperature, since higher T increases EOT without leakage reduction and lower T results in non crystalline (lower-K) films. Sr-rich composition gives overall lower leakage and lower EOT for thin films than the Std. Comp.

### Example 2

### Experimental Details

SrₓTi_{y}O₃ layers were deposited by atomic layer deposition in a cross-flow ASM Pulsar® 3000 reactor on 300 mm Si (100) substrates covered with either 1 nm SiO2 or with 20 nm SiO2/10 nm ALD TiN, at reactor temperatures of 250° C. The precursors were Sr(t-Bu₃ Cp)₂ and Ti(OCH₃)₄ using H₂O as an oxidizer. The Sr and Ti sources were heated to 180° C. and 160° C. respectively to ensure a high enough dose for a saturated ALD process. The temperature of the H₂O container was 15° C. The vapor pressure was set high enough the achieve STO deposition at temperatures below 300° C. By changing the Sr to Ti-precursor ratio, ALD allows the growth of a wide compositional variety of SrₓTi_{y}O₃ films. The ALD process is done in one-step and does not require any seed layer optimization before deposition of the SrTiOx layer. SrₓTi_{y}O₃ films in the 7-20 nm range were grown mainly on ALD TiN substrates. Different Sr:Ti pulse ratios n*/m* namely 1:1, 4:3, 3:2, 2:1, 3:1 and 4:1 were studied, resulting in different Sr:Ti composition ratios. In this exemplary embodiment composition is indicated by giving the pulse ratios.

The film thicknesses and densities were evaluated by x-ray reflectometry (XRR) while ellipsometry was used to check the uniformity over the wafer (KLA-Tencor ASET F5). The composition and contaminant levels of the films were investigated by means of (i) high resolution Rutherford Backscattering Spectrometry (HRRBS); (ii) Time-of-Flight Secondary Ion Mass Spectrometry TOFSIMS depth profiles using a ION-TOF IV instrument operating in the dual ion beam mode; and (iii) angle resolved x-ray photoelectron spectroscopy (ARXPS) measurements using a Thermo Theta300 instrument with monochromatized Al Kα radiation (1486.6 eV). The SrₓTi_{y}O₃ crystallization temperature and phase were studied by in situ x-ray diffraction while the film roughness and microstructure were assessed by atomic force microscopy (AFM) using a Veeco Dimension 3100 instrument and by transmission electron microscopy (TEM) using a Tecnai F30 at 300 kV. The STO crystallization anneal, when applied, was performed by rapid thermal annealing (RTA) before the top electrode deposition using a Heat-Pulse system with controlled atmosphere ambient. Electrical measurements were performed using Pt top electrodes (diameters 100-500 μm) deposited by e-beam evaporation through a shadow mask using a Pfeiffer PLS 580 tool. C-V, G-V characteristics were measured with an Agilent 4284A LCR meter while I-V measurements were carried out using a Keithley 2602 multimeter. The Keithley 2602 has a limited current accuracy of ˜10 pA, but allows for fast, automated screening of samples. To better understand the conduction mechanisms in those films, macroscopic electrical characterizations were complemented by microscopic conductive AFM (C-AFM) measurements. The Veeco Dimension 3100 instrument was converted from AFM to CAFM simply by (i) changing the tips for contact mode imaging by tips with Pt/Ir coating (20-30 nm) for electrical measurements and (ii) replacing the sense amplifier. Finally, the optical band gaps of SrₓTi_{y}O₃ with various Sr-contents were measured by spectroscopic ellipsometry using a Sopra GES 5 Optical platform with spectral range from 800 to 190 nm.

A first-principles Density Functional Theory (DFT) linear response approach was used to calculate the dielectric constants and band gap of a series of SrₓTi_{y}O₃ compositions (from stoichiometric to strontium rich): SrTiO₃, Sr₂TiO₄, Sr₃Ti₂O₇ and Sr₄Ti₃O₁₀.

### Physical Analysis

Thickness and Uniformity.

The SrₓTi_{y}O₃ thickness uniformity measured by ellipsometry over 300 mm wafers indicated a within wafer thickness non-uniformity ≦2.5%. In addition, the STO film thicknesses and densities were measured using XRR on representative samples before and after crystallization anneals. Typical thickness contraction was about 10% after an anneal of 600° C. in N₂ for 1 min, the film density increasing from ˜85% to ˜95% of the bulk value (5.12 g/cm³).

Composition and Contamination Analysis

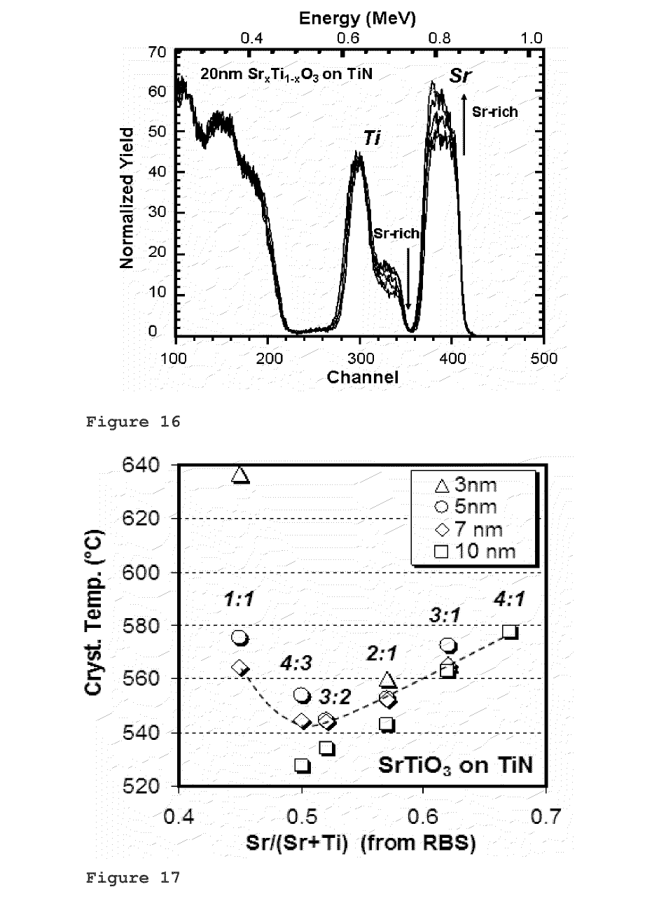

FIG. 16 presents the Sr and Ti HRRBS depth profiles of as deposited 20 nm thick SrₓTi_{y}O₃ films with Sr:Ti ALD pulse ratios ranging from 4:3 (stoichiometric) to 4:1 (67% Sr). As expected, the Sr and Ti signals were found to be dependent upon the Sr:Ti pulse ratio, the Sr (respectively Ti) signal increasing (respectively decreasing) with increasing the Sr:Ti pulse ratio. The extracted film compositions are presented in table 1 below as a function of the ALD Sr:Ti pulse ratios.

TABLE 1
ALD Sr:Ti pulse ratios and corresponding compositions
(atomic %) measured by High Resolution Rutherford
Backscattering Spectrometry (HRRBS)

| | Sr/(Sr + Ti) (at. %) |
|---|---|
| ALD Pulse ratio (Sr:Ti) | from HRRBS |
| 1:1 | 45 |
| 4:3 | 50 |
| 3:2 | 52 |
| 2:1 | 57 |
| 3:1 | 62 |
| 4:1 | 67 |

The composition (Sr:Ti ratio) uniformity over the wafer was excellent (<1.4%). Furthermore, the composition was proven not to be affected (within experimental error 2%) by a change in the underlying substrate nor by an anneal at 600° C. (for 1 min in N₂ atmosphere). TOFSIMS profiles indicated low C, F and Cl contamination in the bulk of the films. The C contaminant level measured by XPS was below the detection limits (<1%). The characterization of the SrₓTi_{y}O₃ films was further completed by ARXPS measurements, showing the presence of SrCO₃ on the film surface. For as deposited films, the SrCO₃ concentration was found to increase with increasing Sr:Ti ALD pulse ratios. This SrCO₃ concentration can be strongly reduced by a thermal treatment at 600° C. for 1 min in N₂.

Crystallization Behavior

The crystallization behavior of the SrₓTi_{y}O₃ films was assessed by in-situ XRD (θ-2θ geometry) during ramp anneals (0.2° C./s) in N₂. As-deposited SrₓTi_{y}O₃ films are amorphous and crystallize into the perovskite STO phase at temperatures in the 520-640° C. range. The crystallization temperature strongly depends on film composition and thickness as show in FIG. 17. Stoichiometric SrTiO₃ ([Sr/(Sr+Ti)]˜0.5) shows the lowest crystallization temperature for a given thickness. As expected, thinner films require a higher temperature to crystallize but the impact of thickness on crystallization temperature seems more pronounced when increasing the Ti-content.

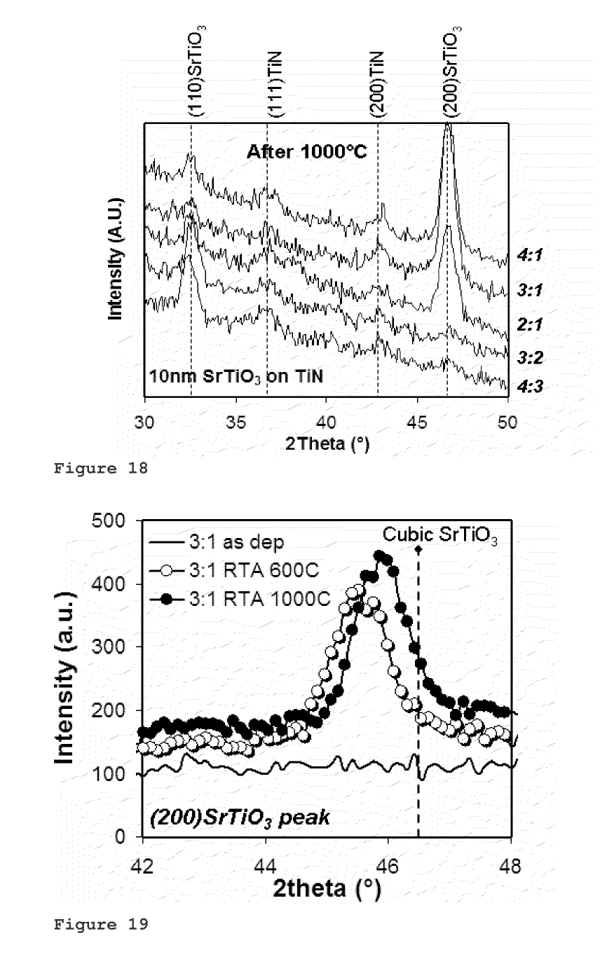

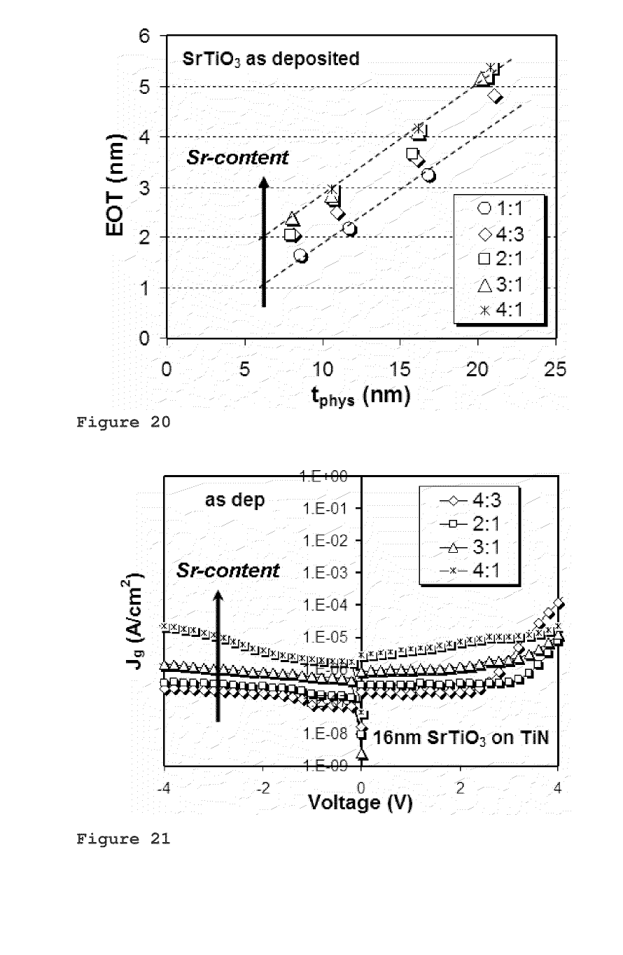

In-situ XRD reveals two other noticeable features regarding the impact of composition on the crystallization behavior of SrₓTi_{y}O₃ films. While all films crystallize into the perovskite structure, the relative intensities of the SrₓTi_{y}O₃ Bragg peaks change drastically with composition. To better illustrate that point, θ-2θ scans were taken after the complete ramp anneal as shown in FIG. 18. Stoichiometric SrTiO₃ films deposited on TiN exhibit a XRD pattern close to the one reported for bulk polycrystalline SrTiO₃ films. The addition of strontium induces a change in the texture of the films; Sr-rich films being more (200) oriented. This effect is strongly related to the underlying layer as no drastic texture change was observed when depositing SrTiO₃ with the same processing parameters directly on Si.

The second observation relies on the fact that the STO peak positions after anneal at 600° C. were found to be shifted with respect to the reported bulk perovskite STO values, but approach the bulk values with higher annealing temperature. This effect is present especially for Sr-rich films as shown in FIG. 19 (10 nm 3:1 film). This suggests the excess Sr may be in solution in STO after low crystallization temperature anneals and expelled out of STO grains at higher temperature.

To support this assumption, SEM plan view images were taken on 10 nm stoichiometric (4:3) and Sr-rich (3:1) films annealed at various temperatures. Stoichiometric films are amorphous for annealing temperature up to 525° C. In agreement with IS-XRD, crystalline features, namely SrTiO₃ grains and star-shaped patterns, can be observed at 600° C. The appearance of the star-shaped patterns in the layers has been attributed by TEM analyzes to stress in the layer After crystallization anneal at 700° C. for 1 min in N₂, cracks appear on the film surface of stoichiometric SrTiO₃ films. On the other hand, when annealed at 700° C. for 1 min in N₂, Sr-rich films exhibit the formation of large Sr-rich crystals. At 600° C., Sr-rich films are crystalline (grain size ˜40 nm) as can been seen in the TEM cross sections and in agreement with IS-XRD results but there is no formation of Sr-rich crystals. At 550° C. the Sr-rich STO films are still amorphous. These SEM observations are in good agreement with a scenario involving the presence of excess Sr in solution at low crystallization annealing temperatures and segregation out of the SrTiO₃ grains at higher temperatures.

### Electrical Evaluation

As-Deposited SrₓTi_{y}O₃ Films

The electrical properties of as-deposited SrₓTiyO₃ based capacitors are summarized in FIGS. 17 and 18.

FIG. 20 shows the EOT evolution of as-deposited films with various Sr:Ti ratios as a function of their physical thickness. Two main conclusions can be drawn based on these results. For all compositions, the EOT varies linearly with the film thickness. Moreover the slope is rather similar for all compositions suggesting that the intrinsic (“bulk”) dielectric constant of the amorphous layers is only slightly affected by changes in the film composition. The extracted relative dielectric K values range from 16 to 18. On the other hand, for every given thickness, the EOT value increases systematically with increasing Sr-content. This indicates that the interface between SrₓTi_{y}O₃ layers and the electrodes is sensitive to the film composition. It is believed that the SrCO₃ layers observed on the film surfaces might be responsible of that EOT penalty; the SrCO₃ amount increasing with the Sr-content.

FIG. 18 shows the leakage current density Jg-V curves of 16 nm as deposited SrₓTi_{y}O₃ films with various Sr-contents. Surprisingly, the increase in EOT observed for Sr-rich films is linked with an increase in the leakage current. This observation suggests differences in the barrier height between the SrₓTi_{y}O₃ film and the electrodes potentially due to the various SrCO₃ amounts observed in the films.

Crystalline SrₓTi_{y}O₃ Films: Influence of the Composition on EOT and k

FIG. 19 shows the capacitance (measured at 0V, 1 kHz) as a function of capacitor size for crystalline SrₓTi_{y}O₃ films (annealed at 600° C. for 1 min in N₂) with compositions (Sr/(Sr+Ti)) ranging from 45% to 62%. For all compositions, the measured capacitance scales linearly with area (while the conductance remains <10 μS for all capacitor sizes). Furthermore, Sr-enrichment of the SrₓTi_{y}O₃ films results systematically (for a given capacitor size) in lower capacitance.

FIG. 23 further compares the electrical characteristics of a MIM capacitor having a stack of a Pt top electrode 13/a SrₓTi_{y}O₃ insulating layer 12/a TiN bottom electrode 13 capacitors with various ALD pulse ratios and thicknesses after crystallization anneal at 600° C. As already seen in FIG. 21 a linear relationship between EOT and physical thickness is observed. Nevertheless, in contrast with as-deposited films, the Sr-content has a significant impact on the proportionality factors between EOT and physical thicknesses.

The extracted relative dielectric constant K values are presented in FIG. 24a as a function of SrₓTi_{y}O₃ composition. The dielectric constant decreases monotonously with increasing Sr-content (K˜210 for stoichiometric 4:3 films and K˜56 for Sr-rich 3:1 films). The decrease in K value with increasing Sr content observed experimentally is in qualitative agreement with the trend predicted by ab-initio modeling for the ideal Ruddlesden-Popper phases. Furthermore, the extrapolation of EOT to zero t_{phys} shown on FIG. 24b would suggest a decrease of interfacial EOT with increasing Sr-content. These extrapolations should be regarded with caution considering possible sources of fluctuations in the EOT extractions. Nevertheless, as already shown on FIG. 18, the texture of the SrₓTi_{y}O₃ films was proven to vary with the Sr-content. This texture change should not affect drastically the dielectric properties of the bulk SrₓTi_{y}O₃, considering that SrₓTi_{y}O₃ has a cubic symmetry, but might corroborate the lower interfacial EOT extrapolated for Sr-rich films.

Crystalline SrₓTi_{y}O₃ Films: Influence of the Composition on the Leakage Properties

The leakage properties of 16 nm crystalline SrₓTi_{y}O₃ films with the different compositions of interest are depicted in FIG. 25. For the same physical thickness, it is clear that Sr-rich films show a much lower leakage current. To better understand this phenomenon, two factors were considered.

The “intrinsic” modification of the SrₓTi_{y}O₃ band gap as a function of the Sr:Ti ratio was evaluated by means of spectroscopic ellipsometry (for 20 nm SrₓTi_{y}O₃ films deposited on SiO₂ and annealed at 600° C. for 1 min in N₂). The extracted optical band gaps increase (from 3.7 eV to 4 eV) with increasing Sr-content (from stoichiometric 3:2 to Sr-rich 4:1) suggests a higher band offset between the high-K STO layer and the electrodes, resulting in lower leakage currents for Sr-rich films. Note that the increase of the band gap with increasing Sr-content is also predicted by ab-initio calculations considering that the excess strontium is accommodated in the structure by formation of RP phases.

To look at possible “extrinsic” factors which could further explain the lower leakages observed for Sr-rich films, conductive AFM measurements were carried out on Ti-rich (1:1 ALD pulse ratio) and Sr-rich (3:1 ALD pulse ratio) films after crystallization anneal at 600° C. for 1 in in N₂. Ti-rich films show non-uniform distribution of the leakage spots. The clustering of leakage paths becomes more apparent with increasing the Ti-rich SrTiO₃ film thickness from 10 nm to 15 nm. Low leakage areas of ˜220-250 nm diameter are surrounded by a 2-dimensional network of leakage paths. Similar behavior has been observed on stoichiometric SrTiO₃ films. Knowing that the films were all crystalline, the leakage non-uniformity may be attributed either to higher leakage at grain boundaries due to segregation of Sr or Ti for instance, or by micro-cracks in the films. Most likely the second scenario is at the origin of the observed patterns for the following reasons: (i) CAFM investigations have shown that the leakage occurs predominantly in the bulk of the grains and not at grain boundaries; (ii) clear cracks have been seen present after annealing at 700° C. for stoichiometric films as also observed in Ti-rich films. On the other hand, quite uniform distributions of leakage spots were demonstrated for Sr-rich films suggesting no obvious formation of cracks in these films. The films are very smooth (RMS roughness ˜0.17 nm). This is in total agreement with the observations made by SEM.

The experimental results systematic study of physical and electrical characterization of SrₓTi_{y}O₃ thin films 11 deposited on TiN bottom electrode 12 by ALD with various Sr:Ti pulse n*/m* ratios (namely 1:1, 4:3, 3:2, 2:1, 3:1 and 4:1). Several conclusions can be drawn:
(i) The deposition process has been shown to be well controlled in terms of composition and thickness uniformity.
(ii) Careful composition analysis of the films was done by HRRBS, TOFSIMS and ARXPS. Despite the overall good control of the composition and low levels of bulk contaminants, ARXPS have also shown the presence of SrCO₃ at the SrₓTi_{y}O₃ film surface. The amount of SrCO₃ increases with the Sr-content for as deposited films and can be significantly reduced by crystallization anneal.
(iii) The impact of Sr-content and thickness upon the SrₓTi_{y}O₃ film crystallization was studied by in situ XRD. The crystallization temperature of stoichiometric films (Sr:Ti=4:3 or 3:2) has been shown to be lower than for the other SrₓTi_{y}O₃ compositions. Furthermore, in situ XRD measurements have shown a change in the film texture with increasing Sr content. Also, the diffraction peaks corresponding to Sr-rich SrₓTi_{y}O₃ films annealed at 600° C. appear at lower angles than the state-of-the-art peak positions of bulk SrTiO₃ perovskites. Even if the mechanisms underlying the accommodation of excess Sr by the SrₓTi_{y}O₃ structure remains unclear. Sr may be in solution in SrₓTi_{y}O₃ after low temperature crystallization anneals and expelled out of SrTiO₃ grains at higher temperatures to form Sr-rich grains.
(iv) Clear tradeoff between low EOT and low leakage was observed for crystalline films. In the range of studied thicknesses, Sr-rich films show higher EOT (lower K) values and lower leakage current than stoichiometric or Ti-rich films but extrapolation to zero physical thicknesses would suggest lower interfacial EOT for Sr-rich composition. The EOT and leakage dependence upon Sr-content, predicted by ab-initio modeling, were supported by electrical evidences and also by optical band-gap extractions by spectroscopic ellipsometry. C-AFM investigation suggests that the leakage increase observed for Ti-rich films might also originate from microcracks formation in the film possibly due higher stress in the layer.

The conclude, the above experimental observations show that the physical and electrical properties of SrₓTi_{y}O₃ are extremely sensitive to the Sr:Ti ratio and prove that a careful choice of the composition is necessary for a targeted device application.

In the previous paragraphs and embodiments a MIMcap device 10 and methods for manufacturing MIMcap device 10 were disclosed having a non-stoichiometric SrₓTi_{y}O₃ insulating layer 12 sandwiched between a bottom electrode 11, comprising Ti, and a top electrode 13. The non-stoichiometric SrₓTi_{y}O₃ insulating layer 12 has a Sr-to-Ti atomic ratio x/y>1 and is Sr rich. Instead of Sr also Ba or a combination of Sr and B can be used to form the non-stoichiometric metal-titanium-oxide insulating layer. Hence the insulating layer 12, as discussed in the foregoing paragraphs and embodiments, can generally be described as a [Ba_{1-q} Sr_{q}]ₓTi_{y}O_{z} oxide with q, x, y, z being integers and x/y>1 to obtain a non-stoichiometric oxide which is rich on alkaline earth metal Ba and/or Sr. If q=0, then a Barium-Titanium oxide BaₓTi_{y}O_{z} is obtained while, if q=1, the Strontium-Titanium oxide SrₓTi_{y}O_{z} is obtained.

1. A metal-insulator-metal capacitor comprising;
a stack of a bottom electrode, an insulating layer, and a top electrode, whereby the insulating layer is a [Ba_{1-q}Sr_{q}]ₓTi_{y}O_{z} oxide, with q, x, y, z being integers, 0<q<1 and (x/y)>(1/1).

2. The capacitor of claim 1, wherein:
z=3, and the insulating layer is [Ba_{1-q}Sr_{q}]ₓTi_{y}O₃ oxide.

3. The capacitor of claim 1, wherein:
q=1, and the insulating layer is a SrₓTi_{y}O_{z} oxide.

4. The capacitor of claim 1, wherein:
q=0, and the insulating layer is a BaₓTi_{y}O_{z} oxide.

5. The capacitor of claim 1, wherein:
(1/1)<(x/y)<(4/1).

6. The capacitor of claim 1, wherein:
the bottom electrode comprises Ti.

7. The capacitor of claim 6, wherein:
the bottom electrode consists of TiN.

8. A DRAM memory cell comprising
a metal-insulator-metal capacitor, and
a selection device,
wherein the metal-insulator-metal capacitor comprises a stack of a bottom electrode, an insulating layer, and a top electrode, whereby the insulating layer is a [Ba_{1-q}Sr_{q}]ₓTi_{y}O_{z} oxide, with q, x, y, z being integers, 0<q<1 and (x/y)>(1/1).

9. The DRAM memory cell of claim 8, wherein,
q=1, and the insulating layer is a SrₓTi_{y}O_{z} oxide.

10. The DRAM memory cell of claim 8, wherein:
q=0, and the insulating layer is a BaₓTi_{y}O_{z} oxide.

11. The capacitor of claim 8, wherein:
(1/1)<(x/y)<(4/1).

12. The capacitor of claim 8, wherein:
the bottom electrode comprises Ti.

13. A method for manufacturing a metal-insulator-metal capacitor, the method comprising;
forming a bottom electrode,
forming an insulating layer on the bottom electrode, and
forming a top electrode on the insulating layer,
wherein the insulating layer is a [Ba_{1-q}Sr_{q}]ₓTi_{y}O_{z} oxide, with q, x, y, z being integers, 0<q<1 and (x/y)>(1/1).

14. The method of claim 13, wherein:
z=3, and the insulating layer is [Ba_{1-q}Sr_{q}]ₓTi_{y}O₃ oxide.

15. The method of claim 13, wherein:
q=1, and the insulating layer is a SrₓTi_{y}O_{z} oxide.

16. The method of claim 13, wherein:
q=0, and the insulating layer is a BaₓTi_{y}O_{z} oxide.

17. The method of claim 13, wherein:
(1/1)<(x/y)<(4/1).

18. The method of claim 13, wherein:
the bottom electrode comprises Ti.

19. The method of claim 18, wherein:
the bottom electrode consists of TiN.

20. The method claim 13, wherein:
the insulating layer is formed by Atomic Layer Deposition.

21. The method of claim 13, wherein:
the insulating layer is formed directly on the bottom electrode (TiN), and
the method further comprises:
performing a anneal step on the as-formed insulating layer thereby bringing the insulating layer into the crystalline perovskite phase.
